(19) United States
(12) Patent Application Publication
(10) Pub. No.: US 2024/0379377 A1
(43) Pub. Date: Nov. 14, 2024

(54) SUBSTRATE PROCESSING METHOD AND SUBSTRATE PROCESSING APPARATUS

(71) Applicant: Tokyo Electron Limited, Tokyo (JP)

(72) Inventors: Tadahiro ISHIZAKA, Nirasaki City (JP); Shinya OKABE, Nirasaki City (JP); Hideaki YAMASAKI, Hillsboro, OR (US)

(21) Appl. No.: 18/648,903

(22) Filed: Apr. 29, 2024

(30) Foreign Application Priority Data
May 8, 2023 (JP) 2023-076830

(51) Int. Cl. H01L 21/3205; C23C 16/52; H01L 21/02; H01L 21/321

(52) U.S. Cl. CPC H01L 21/32053; C23C 16/52; H01L 21/02697; H01L 21/32105

(57) ABSTRACT

A substrate processing method includes: by supplying a first metal halide gas including a first metal to a substrate in which an insulator layer is deposited on a silicon layer and a recess portion is formed in the insulator layer, forming a metal layer of the first metal included in the first metal halide gas on a surface of the silicon layer exposed in the recess portion; and subsequently, by supplying a second metal halide gas, which includes a second metal different from the first metal and reacts with the first metal, to the substrate in which the silicon of the silicon layer is diffused to the metal layer to form a metal silicide layer, removing the first metal adhering to a side wall surface of the recess portion.

### CROSS-REFERENCE TO RELATED APPLICATION

This application is based upon and claims the benefit of priority from Japanese Patent Application No. 2023-076830, filed on May 8, 2023, the entire contents of which are incorporated herein by reference.

### TECHNICAL FIELD

The present disclosure relates to a substrate processing method and a substrate processing apparatus.

### BACKGROUND

In a manufacturing process of a semiconductor device, there is processing such that a recess portion, such as a via hole or a trench, is formed in an insulator layer formed on a semiconductor wafer (hereinafter also referred to as “wafer”), which is a substrate, and a conductor, which is a wiring material, is embedded in the recess portion. In this case, in order to electrically connect a member of a lower layer portion in the insulator layer and the conductor embedded in the recess portion, a metal layer for contact (e.g., a titanium (Ti) layer) may be formed, and then, the conductor may be embedded.

Patent Document 1 describes a technique for forming a TiN film used as a barrier metal on a bottom surface of a contact hole and removing the TiN film formed on a side wall of the contact hole by wet etching. In addition, Patent Document 2 describes a technique for forming titanium silicide, which serves as a first contact material, at a bottom surface of a contact hole. The titanium silicide is formed by forming a titanium film on a silicon oxide film deposited on a transfer electrode film made of polysilicon at the bottom surface of the contact hole and silicidizing the titanium film by annealing processing. In this case, unreacted titanium that has not been silicidized is selectively etched away by a mixed solution of ammonia and hydrogen peroxide.

As described above, Patent Documents 1 and 2 disclose techniques for removing TiN or titanium by wet etching.

### PRIOR ART DOCUMENTS

### Patent Documents

Patent Document 1: Japanese Patent Laid-Open Publication No. 2009-26864
Patent Document 2: Japanese Patent Laid-Open Publication No. 2011-238751

### SUMMARY

According to one embodiment of the present disclosure, there is provided a substrate processing method includes: by supplying a first metal halide gas including a first metal to a substrate in which an insulator layer is deposited on a silicon layer and a recess portion is formed in the insulator layer, forming a metal layer of the first metal included in the first metal halide gas on a surface of the silicon layer exposed in the recess portion; and subsequently, by supplying a second metal halide gas, which includes a second metal different from the first metal and reacts with the first metal, to the substrate in which the silicon of the silicon layer is diffused to the metal layer to form a metal silicide layer, removing the first metal adhering to a side wall surface of the recess portion.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1A is a first enlarged longitudinal cross-sectional side view of a wafer according to a comparative example.

FIG. 1B is a second enlarged longitudinal cross-sectional side view of the wafer according to the comparative example.

FIG. 1C is a third enlarged longitudinal cross-sectional side view of the wafer according to the comparative example.

FIG. 1D is a fourth enlarged longitudinal cross-sectional side view of the wafer according to the comparative example.

FIG. 2 is a plan view showing a configuration example of a substrate processing apparatus according to an embodiment of the present disclosure.

FIG. 3 is a longitudinal cross-sectional side view showing a configuration example of a Ti film forming module installed in the substrate processing apparatus.

FIG. 4 is an explanatory diagram showing an example of a flow of wafer processing according to the embodiment of the present disclosure.

FIG. 5A is a first enlarged longitudinal cross-sectional side view of a wafer according to the embodiment of the present disclosure.

FIG. 5B is a second enlarged longitudinal cross-sectional side view of the wafer according to the embodiment of the present disclosure.

FIG. 5C is a third enlarged longitudinal cross-sectional side view of the wafer according to the embodiment of the present disclosure.

FIG. 6 is a plan view showing a modification example of the substrate processing apparatus.

FIG. 7 is a plan view showing a configuration example of a substrate processing apparatus according to a second embodiment of the present disclosure.

FIG. 8 is an explanatory diagram showing an example of a flow of wafer processing according to the second embodiment of the present disclosure.

FIG. 9 is electron microscopy photographs of a longitudinal cross-section of a wafer according to a reference example and the embodiment of the present disclosure.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### Comparative Example

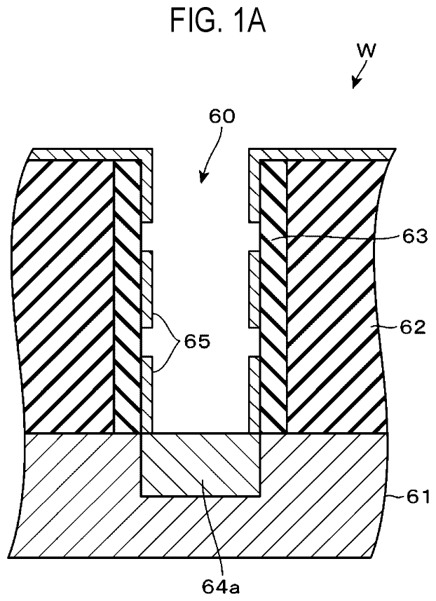

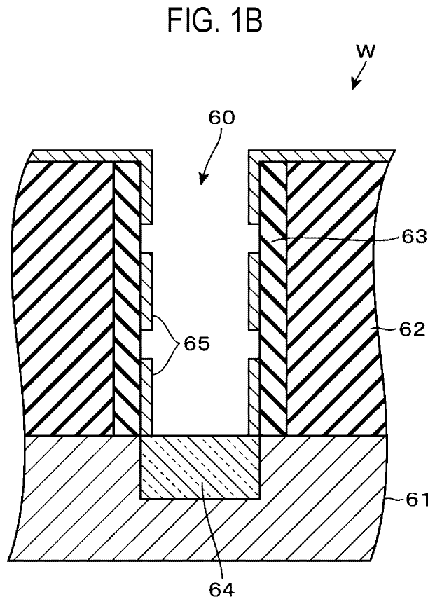

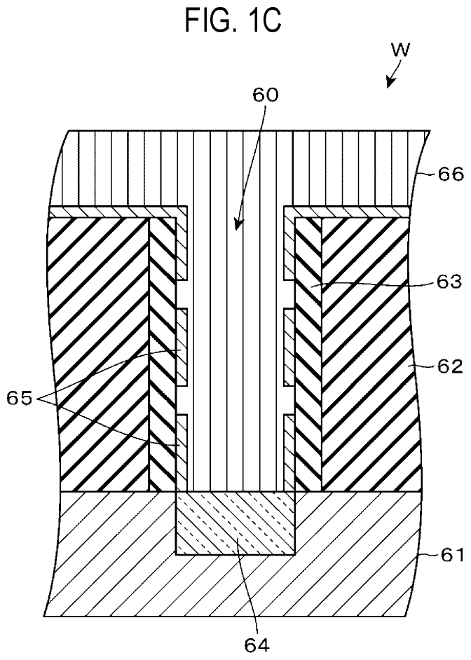

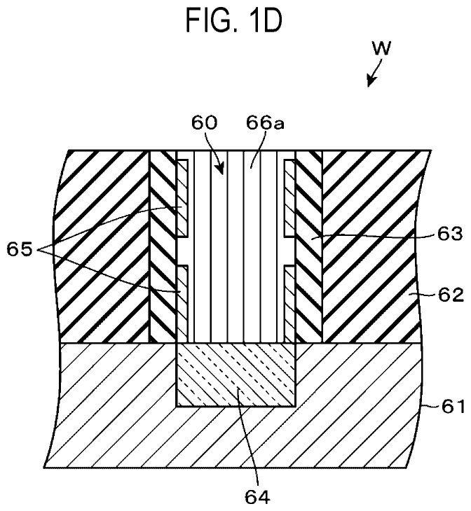

Before describing substrate processing according to an embodiment of the present disclosure, the content of substrate processing according to a comparative example will now be described with reference to FIGS. 1A to 1D, and problems thereof will now be described.

An enlarged longitudinal cross-sectional side view of FIG. 1A shows a configuration near the surface of a wafer W, which is a target of substrate processing, according to a comparative example.

In the wafer W on which substrate processing according to the comparative example is performed, a SiO layer 62, which is an insulator layer, is deposited on a silicon (Si) layer 61, and a recess portion 60 is formed in the SiO layer 62. Further, a SiN layer 63 used during patterning of the recess portion 60 is formed on a side wall of the recess portion 60.

In the wafer W having the above configuration, before a conductor is embedded in the recess portion 60, a Ti layer 64a, which is a metal layer for contact, is formed with respect to a bottom of the recess portion 60 (FIG. 1A). Silicon (Si) atoms diffuse from the Si layer 61 to the Ti layer 64a to form a TiSi layer 64 as shown in FIG. 1B. Thereafter, a conductor, for example, an Ru film 66, is formed on the wafer W, and Ru is embedded in the recess portion 60 (FIG. 1C). Next, an upper surface portion of the wafer W is removed by chemical mechanical polishing (CMP). Then, the wafer W in which a Ru wiring 66a is embedded in the recess portion 60 can be obtained as shown in FIG. 1D.

In the substrate processing described above, as shown in FIG. 1A, when forming the Ti layer 64a with respect to the bottom of the recess portion 60, Ti may adhere in spots to a side wall surface of the recess portion 60. Hereinafter, Ti adhering to the side wall surface of the recess portion 60 will also be referred to as an adhesion Ti 65.

Ti has a higher resistance value than Ru. On the other hand, as semiconductor devices become more highly integrated, an opening area of the recess portion 60 is being miniaturized. For example, if the adhesion Ti 65 is formed on both side wall surfaces of the recess portion 60 having an opening diameter of 10 nm, even when the thickness of the adhesion Ti 65 is approximately 0.5 nm to 1.0 nm, the opening diameter of the recess portion 60 is reduced by approximately 10% to 20%. As a result, an embedded area of the Ru wiring 66a may be reduced and wiring resistance may increase.

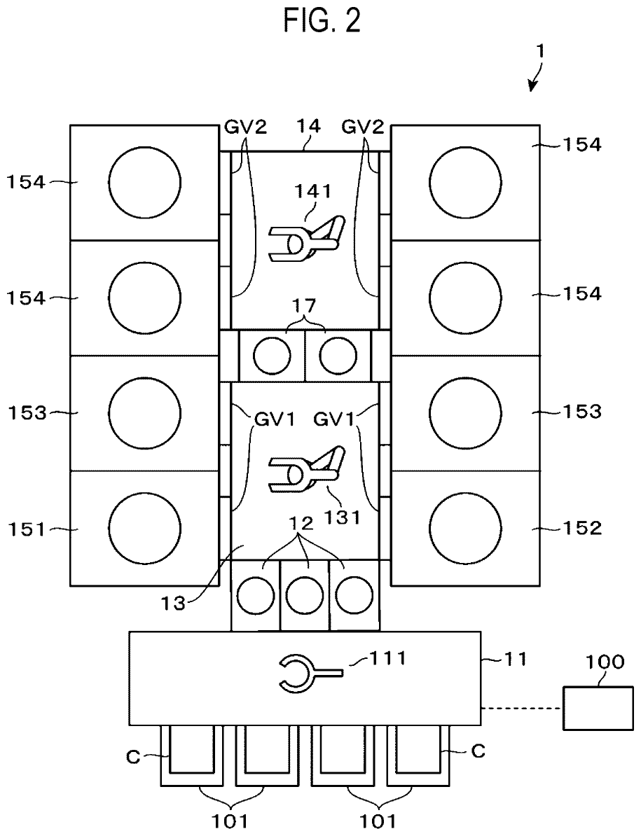

Therefore, in substrate processing of the embodiment described below, after forming the Ti layer 64a (TiSi layer 64), a processing for removing the adhesion Ti 65 adhering to the side wall of the recess portion 60 is performed. Hereinafter, a detailed description of the substrate processing according to the embodiment will be given with reference to FIGS. 2 to 5C.

### <Substrate Processing Apparatus 1>

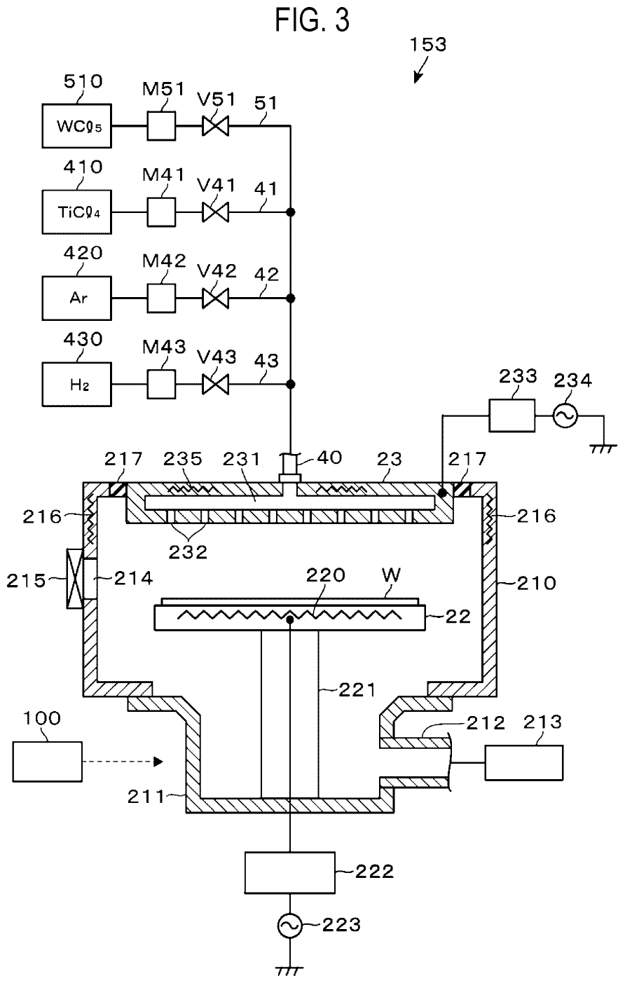

Hereinafter, an apparatus, which forms the TiSi layer 64 for contact with respect to the recess portion 60 formed on the wafer W and then forms the Ru film 66, (hereinafter referred to as “substrate processing apparatus 1”) will be described with reference to FIGS. 2 and 3 according to an embodiment. FIG. 2 is a plan view schematically showing a configuration example of a substrate processing apparatus 1. The substrate processing apparatus 1 includes an atmospheric transfer chamber 11, a load lock chamber 12, a first substrate transfer chamber 13, a second substrate transfer chamber 14, and a plurality of processing modules 151 to 154.

The first substrate transfer chamber 13 and the second substrate transfer chamber 14 are each configured in a rectangular shape when viewed in a plan view and are connected via, for example, two delivery portions 17. The interiors of the first and second substrate transfer chambers 13 and 14 and the delivery portions 17 are set to a vacuum pressure atmosphere, and the pressures thereof are configured to be aligned with each other. Furthermore, first and second transfer mechanisms 131 and 141 are disposed inside the first and second substrate transfer chambers 13 and 14, respectively.

The delivery portion 17 is configured to deliver a wafer between the delivery portion 17 and the first transfer mechanism 131 installed in the first substrate transfer chamber 13 or between the delivery portion 17 and the second transfer mechanism 141 installed in the second substrate transfer chamber 14. The first substrate transfer chamber 13, the second substrate transfer chamber 14, and the delivery portion 17 correspond to a vacuum transfer chamber of the embodiment. Further, the first transfer mechanism 131 and the second transfer mechanism 141 correspond to a substrate transfer mechanism of the embodiment.

A direction in which the substrate transfer chambers 13 and 14 are disposed is referred to as a length direction, a direction in which the first substrate transfer chamber 13 is disposed is referred to as a front side, and a direction in which the second substrate transfer chamber 14 is disposed is referred to as a back side. In this case, the atmospheric transfer chamber 11 set to an atmospheric pressure atmosphere is connected to the front side of the first substrate transfer chamber 13 via, for example, the three load lock chambers 12. Respective transfer ports for wafer and gate valves for opening and closing the transfer ports are present between the first and second substrate transfer chambers 13 and 14 and the delivery portion 17, between the load lock chambers 12 and the first substrate transfer chamber 13, and between the load lock chambers 12 and the atmospheric transfer chamber 11 but are not shown in the drawings.

Four load ports 101, for example, are connected to the atmospheric transfer chamber 11, and a carrier C containing a plurality of wafers W is placed in each load port 101. In the atmospheric transfer chamber 11, an atmospheric transfer mechanism 111 is installed, and the wafer W can be transferred between the carrier C connected to the atmospheric transfer chamber 11 and the load lock chambers 12.

When viewed from the front side, one chemical oxide removal (COR) module 151 and one post heat treatment (PHT) module 152 are connected to two wall portions of left and right of the first substrate transfer chamber 13, respectively, and two Ti film forming modules 153 are connected to the two wall portions of the first substrate transfer chamber, respectively. The first transfer mechanism 131 installed in the first substrate transfer chamber 13 is configured to transfer the wafer W between the four modules 151 to 153, the delivery portion 17, and the load lock chambers 12. In FIG. 2, symbols GV1 denote gate valves.

COR processing performed by the COR module 151 and PHT processing performed by the PHT module 152 are pre-cleaning processes that remove a natural oxide film (SiOₓ) on the surface of the Si layer 61 exposed in the recess portion 60 described above. Specifically, the COR module 151 is configured to perform etching processing (COR processing) of the natural oxide film using hydrogen fluoride (HF) gas and ammonia (NH₃) gas. Further, the PHT module 152 is configured to perform PHT processing in which a reaction product generated by COR processing is sublimated and removed by heating the wafer W.

Further, the Ti film forming module 153 is configured to form the Ti layer 64a serving as a contact metal layer for contact between the Si layer 61 and the Ru wiring 66a. Furthermore, the Ti film forming module 153 also has a function of removing the adhesion Ti 65 adhering to the side wall surface of the recess portion 60 caused by film formation of the Ti layer 64a. From the viewpoint of performing film formation of the Ti layer 64a, the Ti film forming module 153 corresponds to a first processing module of the embodiment. Further, from the viewpoint of removing the adhesion Ti 65 adhering to the side wall surface of the recess portion 60, the Ti film forming module 153 also corresponds to a second processing module of the embodiment.

A detailed configuration example of the Ti film forming module 153 will be described in detail later with reference to FIG. 3.

Further, when viewed from the front side, a total of four Ru film forming modules 154 is are connected to two wall portions of left and right of the second substrate transfer chamber 14, two of which are connected to the wall portion on the left and two of which are connected to the wall portion on the right. The second transfer mechanism 141 is configured to transfer the wafer W between these four Ru film forming modules 154 and the delivery portion 17. In FIG. 2, symbols GV2 denote gate valves.

Each of the Ru film forming module 154 is configured to perform film formation of the Ru film 66 by, for example, a chemical vapor deposition (CVD) method using a raw material gas of Ru, which is a conductor. The Ru film forming module 154 corresponds to a fourth processing module of the embodiment.

### <Ti Film Forming Module 153>

Next, a detailed configuration example of the Ti film forming module 153 will be described with reference to FIG. 3. The Ti film forming module 153 is configured to form the Ti layer 64a using the plasma CVD method by supplying a film forming gas containing a first metal halide gas, which will be described later, to the wafer W. The Ti film forming module 153 also has a function of removing the adhesion Ti 65 adhering to the side wall surface of the recess portion 60 by supplying a second metal halide gas, which will be described later, to the wafer W after forming the Ti layer 64a.

FIG. 3 is a longitudinal cross-sectional side view of a Ti film forming module 153 of the embodiment. The Ti film forming module 153 includes a substantially cylindrical metal processing container 210 that has corrosion resistance to chlorine and is grounded. An exhaust chamber 211 of, for example, a cylindrical shape that protrudes downward is formed in a center of a bottom surface of the processing container 210, and an exhaust path 212 is connected to a side surface of the exhaust chamber 211. A vacuum exhauster 213 including, for example, a pressure regulating valve consisting of a butterfly valve or a vacuum pump is connected to the exhaust path 212. The vacuum exhauster 213 serves to evacuate an interior of the processing container 210 to a preset vacuum pressure. The wafer W is processed in a space within the processing container 210.

A loading/unloading port 214 is formed on a side surface of the processing container 210 for loading/unloading the wafer W into/from the first substrate transfer chamber 13 described above. The loading/unloading port 214 is configured to be openable/closable by a gate valve 215 (GV1 in FIG. 2). Further, a heater 216 for adjusting temperature inside the processing container 210 is embedded in a wall portion constituting the processing container 210.

Further, a stage 22 for holding the wafer W substantially horizontally is provided inside the processing container 210. The stage 22 is supported by a supporter 221 extending from a bottom of the exhaust chamber 211. A heater 220, which is a heating portion, is embedded in the stage 22 and can heat the wafer W to a set temperature. In this example, a heating temperature of the wafer W is set in a range of 350 to 800 degrees C., for example, 450 degrees C.

Further, a radio-frequency power source 223 that supplies radio-frequency power for attracting ions is connected to the stage 22 via a matcher 222. Furthermore, in the stage 22, a lifting pin, which is not shown, is installed for holding and then raising and lowering the wafer W placed on the stage 22. The wafer W can be delivered between the stage 22 and the first transfer mechanism 131 in the first substrate transfer chamber 13 by raising and lowering the lift pin.

Further, a flat, disc-shaped shower head 23 for supplying a substrate processing gas to the wafer W is installed in a ceiling surface of the processing container 210. The shower head 23 is attached to the processing container 210 via an insulating member 217.

A diffusion chamber 231 for diffusing gas is formed inside the shower head 23. Further, a plurality of discharge holes 232 for discharging gas toward the wafer W is distributively formed on a bottom surface of the shower head 23. In addition, a heater 235 is embedded in an upper surface side of the shower head 23.

A radio-frequency power source 234 that supplies radio-frequency power for plasma formation is connected to the above-mentioned shower head 23 via a matcher 233. That is, the substrate processing apparatus 1 of the present disclosure constitutes a parallel plate type plasma processing apparatus by the shower head 23 serving as an upper electrode and the stage 22 serving as a lower electrode. By placing the wafer W in a space between the shower head 23 and the stage 22, supplying a film forming gas and applying radio-frequency power, the gas is ionized to form plasma. The radio-frequency power source 234 may be configured to supply radio-frequency power of any frequency of 450 kHz, 13.56 MHz, 27 MHz, 40 MHz, 60 MHZ, 100 MHz, or 2.45 GHz. For example, the radio-frequency power source 234 supplies radio-frequency power in a range of high frequencies greater than 0 W and equal to or less than 2,000 W.

Furthermore, a downstream end of a gas supply path 40 is connected to the diffusion chamber 231 of the shower head 23. A TiCl₄ gas supply pipe 41, an Ar gas supply pipe 42, and an H₂ gas supply pipe 43 merge on an upstream of the gas supply path 40. The TiCl₄ gas supply pipe 41 is a flow path for supplying TiCl₄ gas, which is a first metal halide gas and includes Ti of a first metal constituting the Ti layer 64a. The Ar gas supply pipe 42 is a flow path for supplying Ar gas added for plasma generation. The H₂ gas supply pipe 43 is a flow path for supplying H₂ gas, which is a reaction gas.

A TiCl₄ gas supply source 410 is connected to an upstream side end of the TiCl₄ gas supply pipe 41, and a flow rate controller M41 and a valve V41 are interposed (a first gas supplier) in this order from an upstream side. Further, an Ar gas supply source 420 is connected to an upstream side end of the Ar gas supply pipe 42, and a flow rate controller M42 and a valve V42 are interposed in this order from an upstream side. An H₂ gas supply source 430 is connected to an upstream side end of the H₂ gas supply pipe 43, and a flow rate controller M43 and a valve V43 are interposed in this order from an upstream side.

A mixed gas (film forming gas) of TiCl₄ gas, H₂ gas, and Ar gas flows into the diffusion chamber 231 of the shower head 23 via the gas supply path 40 and is supplied into the processing container 210 through the discharge holes 232.

Further, a WCl₅ gas supply pipe 51 merges on the upstream side of the gas supply path 40. WCl₅ gas contains a second metal (W) different from the first metal (Ti) and corresponds to a second metal halide gas that reacts with the first metal. A WCl₅ gas supply source 510 is connected to an upstream end of the WCl₅ gas supply pipe 51, and a flow rate controller M51 and a valve V51 are interposed (a second gas supplier) in this order from an upstream side. WCl₅ gas also flows into the diffusion chamber 231 of the shower head 23 via the gas supply path 40 and is supplied into the processing container 210 through the discharge holes 232.

According to the above configuration, in the example shown in FIG. 3, the Ti film forming module 153 has a configuration in which a first processing module that forms the Ti layer 64a and a second processing module that removes the adhesion Ti 65 share the stage 22 and the processing container 210.

### <Other Processing Modules 151, 152, and 153>

Although not shown, the COR module 151, the PHT module 152, and the Ru film forming module 154 are similar to the Ti film forming module 153 described above in that the COR module 151, the PHT module 152, and the Ru film forming module 154 include the processing container 210 and the stage 22. In the COR module 151, HF gas and NH₃ gas used for COR processing are supplied to the processing container 210 via the gas supply path 40. In the PHT module 152, N₂ gas that forms an inert gas atmosphere in which PHT processing is performed is supplied to the processing container 210 via the gas supply path 40.

In the Ru film forming module 154, Ru₃(CO)₁₂ gas, which is a raw material gas for the Ru film 66, and CO gas, which is a carrier gas, are supplied to the processing container 210 via the gas supply path 40. A gas supply source and a flow rate controller that supply Ru₃(CO)₁₂ gas or CO gas correspond to a fourth gas supplier of the present embodiment. The Ru film forming module 154 is configured to form the Ru film 66 by, for example, a thermal CVD method.

Therefore, unlike the Ti film forming module 153 described with reference to FIG. 3, the Ru film forming modules 154 does not include the matcher 233 connected to the shower head 23, the radio-frequency power source 234, the matcher 222 connected to the stage 22, and the higher frequency power source 223.

### <Controller 100>

The substrate processing apparatus 1 having the above-described configuration includes a controller 100 as shown in FIGS. 2 and 3. The controller 100 is constituted by a computer including a storage portion storing a program, a memory, and a central processing unit (CPU). The program is programmed with instructions (steps) that cause the controller 100 to execute substrate processing using various modules 151 to 154 by outputting a control signal to each portion of the substrate processing apparatus 1 and controlling supply and stop of each gas and supply of radio-frequency power. The program is stored in a storage portion of the computer, for example, a flexible disk, a compact disc, a hard disk, a magneto-optical (MO) disk, or a nonvolatile memory and is read from the storage portion and installed in the controller 100.

### <Substrate Processing>

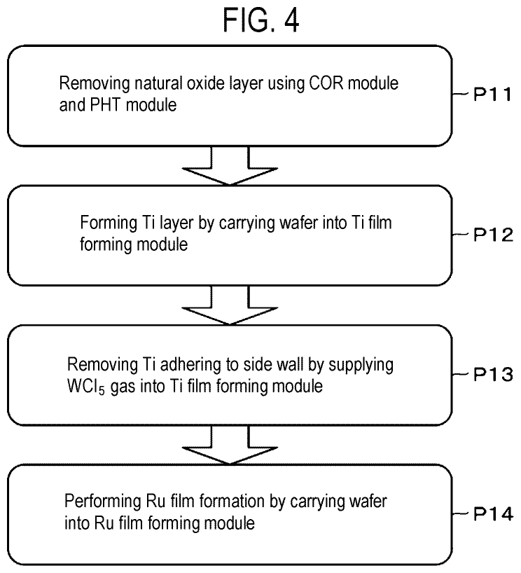

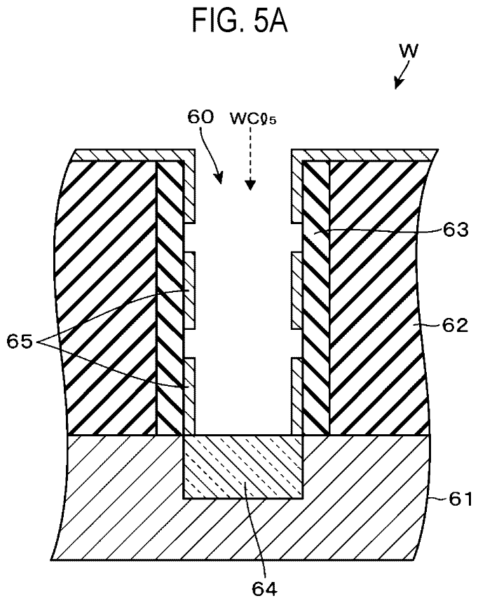

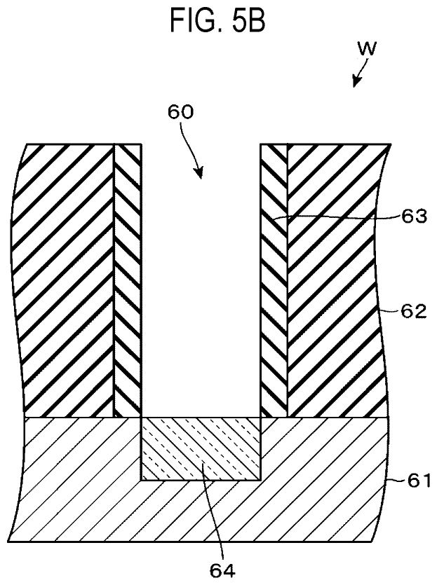

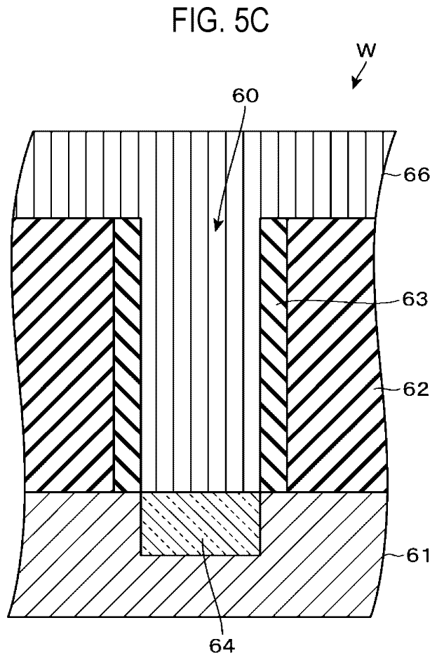

Details of substrate processing implemented using the substrate processing apparatus 1 having the above-described configuration will be described with reference to FIG. 4 and FIGS. 5A to 5C.

In the substrate processing apparatus 1, first, the wafer W accommodated in the carrier C is taken out and transferred to the load lock chamber 12 in an atmospheric pressure atmosphere by the atmospheric transfer mechanism 111, and an interior of the load lock chamber 12 is adjusted to a vacuum pressure atmosphere. Next, the wafer W in the load lock chamber 12 is sequentially transferred by the first transfer mechanism 131 to the COR module 151 and the PHT module 152, and a natural oxide film formed in the Si layer 61 is removed by the modules 151 and 152 (Processing P11 in FIG. 4).

Subsequently, the wafer W is transferred by the first transfer mechanism 131 to the Ti film forming module 153 in which the Ti layer 64a is formed (Processing P12 in FIG. 4, Step of forming a metal layer of a first metal). In this processing, after placing the wafer W on the stage 22, the vacuum exhauster 213 evacuates the interior of the processing container 210 to a preset pressure in the processing container 210. The heater 220 heats the wafer W to 450 degrees C. as described above.

Thereafter, the gas supply sources 410, 420, and 430 supply TiCl₄ gas, Ar gas, and H₂ gas, respectively, at a preset flow rate, and a film forming gas, which is a mixture of these gases, is introduced into the processing container 210. In addition, radio-frequency power is applied from the radio-frequency power source 234 and the radio-frequency power source 223 to form plasma of the film forming gas, and film formation of Ti is performed on the wafer W.

After performing film formation of Ti for a preset time, supply of the film forming gas and application of the radio-frequency power are stopped. As a result, as described with reference to FIG. 1A, the Ti layer 64a is formed on the bottom surface of the recess portion 60. Silicon diffuses into the Ti layer 64a from the Si layer 61, and the TiSi layer 64 is formed in a short time. Further, due to film formation of Ti, the adhesion Ti 65 may adhere to the side wall surface of the recess portion 60 (FIG. 5A).

Therefore, in the Ti film forming module 153 of the embodiment, after forming the Ti layer 64a, the gas supplied to the processing container 210 is switched to WCl₅ gas while continuing to heat the wafer W. As a result, WCl₅ gas is supplied from the WCl₅ gas supply source 510 at a preset flow rate and introduced into the processing container 210. As shown in FIG. 5A, when WCl₅ gas reaches the wafer W, a reaction represented in Equation (1) below proceeds.

$$4 WC {l}_{5} ( g ) + 5 Ti ( s ) \to 5 {TiCl}_{4} ( g ) + 4 W ( s ) \qquad ( 1 )$$

By proceeding with Equation (1) above, the adhesion Ti 65 on the side wall surface of the recess portion 60 can be removed as shown in FIG. 5B (Processing P13 in FIG. 4, Step of removing the first metal). Here, by supplying WCl₅ gas, a part of the surface of the TiSi layer 64 formed on the bottom surface of the recess portion 60 may also be removed. However, as compared to Ti, TiSi is etched slowly by WCl₅. Furthermore, by forming the TiSi layer 64 (Ti layer 64a) of a sufficient thickness, the TiSi layer 64 can remain without losing a function as a contact metal layer.

According to Equation (1), solid tungsten (W) remains when the adhesion Ti 65 is removed. However, since a resistance value of W is smaller than a resistance value of Ti, wiring resistance after the Ru wiring 66a is embedded can be suppressed from increasing as compared to a state in which the adhesion Ti 65 is still formed.

When the adhesion Ti 65 is removed by supplying WCl₅ gas, H₂ gas may be supplied to perform purge processing in order to promote discharge of WCl₅ or TiCl₄ remaining in the processing container 210.

Subsequently, the wafer W is transferred to the Ru film forming module 154 via the first transfer mechanism 131, the delivery portion 17, and the second transfer mechanism 141. An inert gas is supplied to the first substrate transfer chamber 13, the delivery portion 17, and the second substrate transfer chamber 14 to prevent gas diffusion from the film forming module. Pressure is controlled in a range of 20 Pa to 200 Pa, for example, controlled to 100 Pa. In order to prevent surface oxidation during transfer, an arrival vacuum degree of a vacuum exhaust mechanism (not shown) that vacuum-evacuates these spaces (the first substrate transfer chamber 13, the delivery portion 17, and the second substrate transfer chamber 14) is set to 1.33×10⁻⁵ Pa or less. In the Ru film forming module 154, film formation of the Ru film 66 is performed so that Ru is embedded in an upper surface side of the TiSi layer 64 formed in the recess portion 60 (Processing P14 in FIG. 4, Step of embedding a conductor).

Specifically, the wafer W is carried into the processing container 210 of the Ru film forming module 154 and placed on the stage 22. The wafer W is heated by the heater 220 in a range of 130 degrees C. to 200 degrees C., for example, heated to 150 degrees C. Further, pressure inside the processing container 210 is adjusted, and Ru₃(CO)₁₂ gas (containing CO gas which is a carrier gas) is supplied into the processing container 210.

As a result, thermal CVD in which Ru₃(CO)₁₂ supplied into the processing container 210 is thermally decomposed on the wafer W progresses. Then, by performing thermal CVD for a preset period, the Ru film 66 can be embedded in the recess portion 60 from which the adhesion Ti 65 has been removed, as shown in FIG. 5C.

After film formation of the Ru film 66 is completed, the wafer W is transferred to the load lock chamber 12 via the second transfer mechanism 141, the delivery portion 17, and the first transfer mechanism 131. Next, after switching an atmosphere in the load lock chamber 12 to an atmospheric pressure atmosphere, the wafer W after processing is returned to the carrier C by the atmospheric transfer mechanism 111.

According to the embodiment described above, the adhesion Ti 65 on the side wall surface of the recess portion 60 can be removed by WCl₅ gas. As a result, an increase in wiring resistance after the Ru film 66 (Ru wiring 66a) is embedded in the recess portion 60 can be suppressed.

Here, the technique of the present disclosure removes the adhesion Ti 65 by dry etching using WCl₅ gas (second metal halide gas). For this reason, unlike the case in which wet etching is performed, the adhesion Ti 65 can be removed during a series of substrate processing from removal processing (COR processing and PHT processing) of the natural oxide layer of the surface of the Si layer 61 to film formation of the Ru film 66. As a result, it is possible to perform substrate processing within the common substrate processing apparatus 1 without exposing the wafer W to the atmospheric atmosphere, and it is possible to suppress formation of an unnecessary natural oxide film.

Here, as in an example of the Ti film forming module 153 described with reference to FIG. 3, a first processing module that forms the Ti layer 64a and a second processing module that removes the adhesion Ti 65 are not limited to a configuration in which the stage 22 and the processing container 210 are shared. The first processing module and the second processing module may be configured as separate bodies.

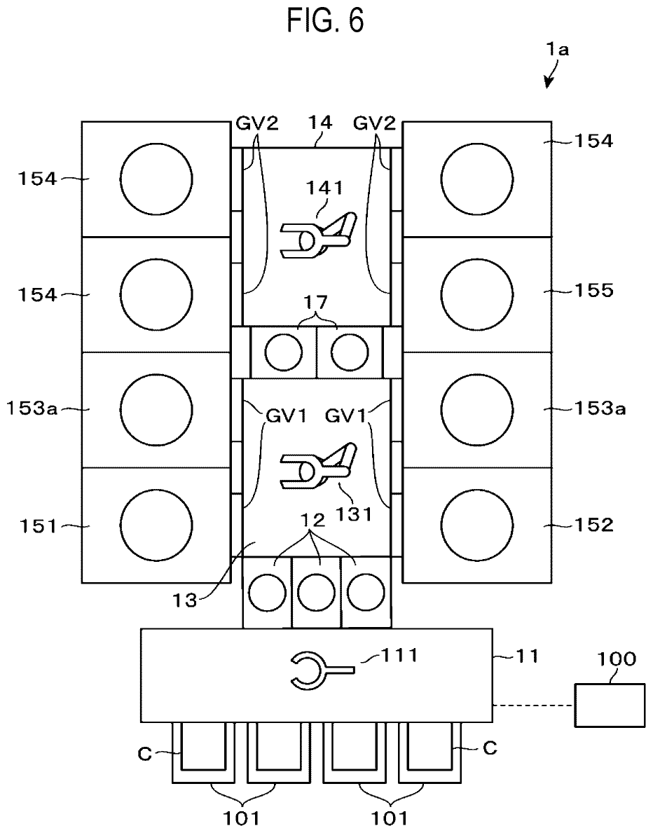

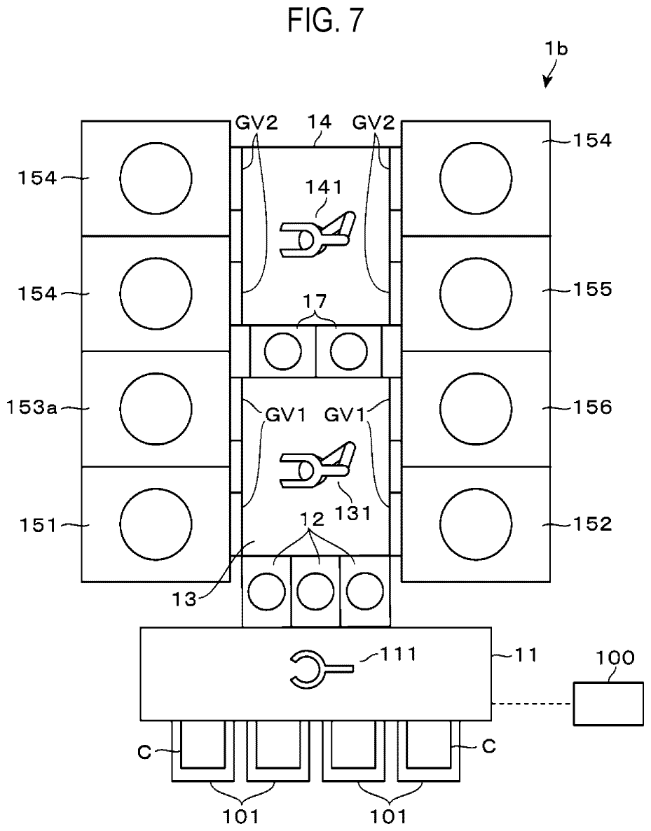

A substrate processing apparatus 1a of FIG. 6 shows an example in which a Ti film forming module 153a, which is a first processing module that has only a function of performing film formation of Ti, and a pre-cleaning module 155, which is a second processing module that has only a function of removing the adhesion Ti 65 using WCl₅ gas are configured as separate bodies. In the substrate processing apparatuses 1a and 1b shown in FIGS. 6 and 7, components common to those of the substrate processing apparatus 1 described with reference to FIG. 2 are assigned the same reference numerals as those shown in FIGS. 6 and 7.

In the substrate processing apparatus 1a, one Ti film forming module 153a is connected to each of the left and right wall portions of the first substrate transfer chamber 13. Furthermore, the pre-cleaning module 155 is connected to a wall portion of one side of the second substrate transfer chamber 14. Since the pre-cleaning module 155 is installed, the number of Ru film forming modules 154 installed in the substrate processing apparatus 1a of the example is three compared to the substrate processing apparatus 1 shown in FIG. 2.

### Second Embodiment

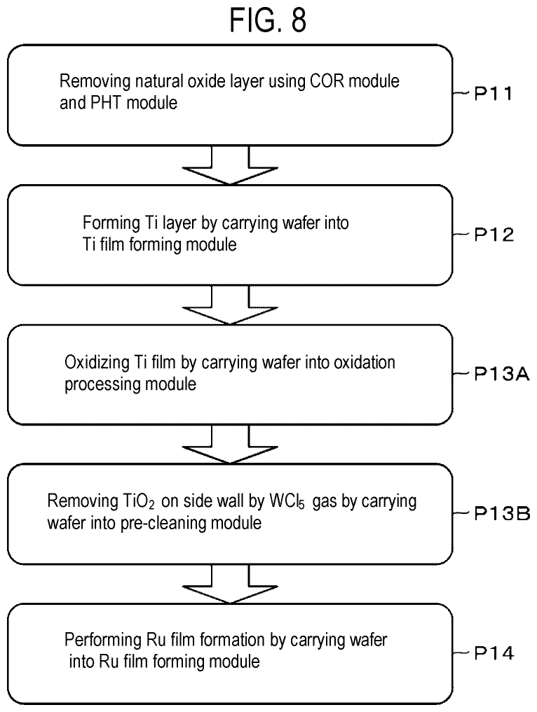

Next, a configuration and operation of the substrate processing apparatus 1b according to a second embodiment will be described with reference to FIGS. 7 and 8. The substrate processing apparatus 1b according to the second embodiment is configured to oxidize the adhesion Ti 65 adhering to the side wall surface of the recess portion 60 and then remove the adhesion Ti 65 using WCl₅ gas. The substrate processing apparatus 1b further includes an oxidation processing module 156 that performs processing of oxidizing the adhesion Ti 65.

Although not shown individually, the oxidation processing module 156 is similar to the Ti film forming module 153 described with reference to FIG. 3 in that the oxidation processing modules 156 includes the processing container 210 and the stage 22. The oxidation processing module 156 is configured such that an oxidizing gas for oxidizing the adhesion Ti 65 is supplied to the processing container 210 via the gas supply path 40. Here, examples of the oxidizing gas include O₂ gas, O₃ gas, H₂O gas, H₂O₂ gas, N₂O gas, and N₂O₂ gas. The Ti film forming module 153 may have a function of converting an oxidizing gas into plasma or may be used without converting the oxidizing gas into plasma.

In the substrate processing apparatus 1b shown in FIG. 7, one Ti film forming module 153a having only a film forming function of Ti and one oxidation processing module 156 are connected to the first substrate transfer chamber 13. Furthermore, one pre-cleaning module 155 is connected to the second substrate transfer chamber 14.

Processing of the wafer W using this substrate processing apparatus 1b will be described with reference to FIG. 8. In FIG. 8, differences from substrate processing according to the first embodiment described with reference to FIG. 4 will mainly be described.

After performing COR processing and PHT processing on the wafer W to be processed using the COR module 151 and the PHT module 152 (Processing P11 in FIG. 8), the wafer W is carried into the Ti film forming module 153a to form the Ti layer 64a (Processing P12 in FIG. 8). Thereafter, processing of oxidizing the adhesion Ti 65 on the side wall surface of the recess portion 60 (P13A in FIG. 8, Step of oxidizing a first metal) is performed on the wafer W on which the Ti layer 64a (TiSi layer 64) has been formed.

Specifically, the wafer W is carried into the processing container 210 of the oxidation processing module 156 and placed on the stage 22, and the wafer W is heated by the heater 220 to a temperature in the range of 100 degrees C. to 400 degrees C., for example. Then, pressure inside the processing container 210 is adjusted, and an oxidizing gas is supplied into the processing container 210. In this case, when converting the oxidizing gas into plasma, energy such as radio-frequency power is supplied.

By the above operation, oxidation of the adhesion Ti 65 progresses in an atmosphere in which the oxidizing gas is supplied. After performing processing using the oxidizing gas for a preset period, supply of the oxidizing gas, heating of the wafer W, etc. are stopped, and the wafer W is transferred to the pre-cleaning module 155.

In the pre-cleaning module 155, the wafer W accommodated in the processing container 210 and placed on the stage 22 is heated to a temperature in the range of 300 degrees C. to 500 degrees C., for example, to 450 degrees C. Then, pressure inside the processing container 210 is adjusted, and WCl₅ gas is supplied to the wafer W. As a result, when WCl₅ gas arrives, a reaction represented in Equation (2) below proceeds.

$$2 {WCl}_{5} ( g ) + TiO ( s ) \to {TiOCl}_{2} ( g ) + 2 {WCl}_{4} ( g ) \qquad ( 2 )$$

By proceeding with Equation (2) above, the adhesion Ti 65 on the side wall surface of the recess portion 60 can be removed (Processing P13B in FIG. 8) similarly to the first embodiment described with reference to FIG. 5B. As shown in Equation (2), since a reaction product of WCl₅ and TiO is a gaseous substance, there is almost no residual effect of tungsten (W).

Here, the TiSi layer 64 formed at the bottom of the recess portion 60 may be oxidized under an atmosphere in which the oxidizing gas is supplied, and TiSiO may be formed. It is difficult to remove SiO contained in TiSiO by WCl₅ gas. In order to avoid such a situation, when forming the Ti layer 64a, the thickness of the Ti layer 64a is formed to be large enough to make it difficult for silicon atoms diffused from the Si layer 61 to reach the surface of the Ti layer 64a. For example, when forming the TiSi layer 64 of a thickness of 5 nm, the thickness of the Ti layer 64a may be approximately 1.5 to 2 times the thickness of 5 nm.

By adjusting the thickness of the Ti layer 64a, exposure of TiSi at the bottom of the recess portion 60 can be avoided, and formation of TiSiO can be suppressed. At the bottom of the recess portion 60, a Ti layer with no exposed silicon atoms is exposed, and this Ti layer is oxidized to form the TiO layer. Then, when the TiO layer is removed using WCl₅ gas, the TiSi layer 64 is exposed at the bottom of the recess portion 60, similar to the example shown in FIG. 5B.

After removing the adhesion Ti 65, the operations of performing film formation of the Ru film 66 and unloading the wafer W after processing are the same as the case of using the substrate processing apparatus 1 described above, and therefore redundant description will be omitted.

### <Variation>

In the substrate processing method described above, the second halide gas used to remove the adhesion Ti 65 is not limited to the example of WCl₅ gas. For example, WCl₆ gas or MoCl₅ gas may be used.

Furthermore, the first metal formed in the recess portion 60 is not limited to Ti, and the metal formed using the first metal halide gas may be other metals. Even in this case, the first metal adhering to the side wall surface of the recess portion 60 can be removed by supplying the second metal halide gas that reacts with the first metal.

### Embodiments

### (Experimentation)

A film containing Ti was formed on the surface of a silicon wafer, and the effect of removal by WCl₅ gas was confirmed.

### A. Experimental Conditions

(Reference Example) A TiN layer was formed on the surface of a flat wafer W by plasma CVD of a film forming gas containing TiCl₄, and a Ru layer was further deposited on a surface of the TiN layer.

(Embodiment) In the same method as in the reference example, the TiN layer was formed on the surface of the flat wafer W, the wafer W was heated to 450 degrees C., and WCl₅ gas was supplied for 20 seconds at a pressure of 1,200 Pa and a flow rate of 1.8 sccm. Thereafter, H₂ gas was supplied for 100 seconds at a flow rate of 1,200 sccm while maintaining temperature and pressure.

### B. Experimental Results

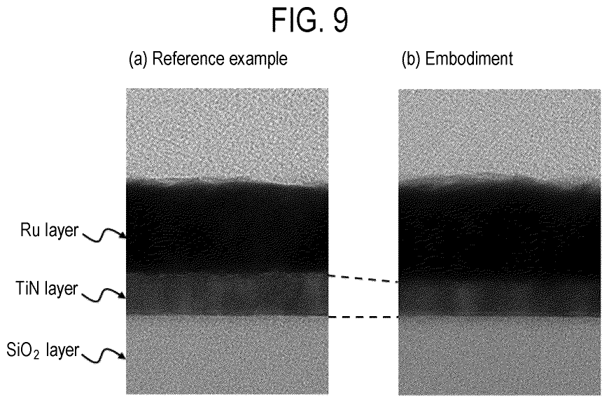

Transmission Electron Microscopy (TEM) photographs of the wafer W according to the reference example and the embodiment of the present disclosure are shown in (a) and (b) of FIG. 9. Comparing the photographs, it can be appreciated that in the embodiment of (b) of FIG. 9, the thickness of the TiN layer is reduced by WCl₅ gas processing for 20 seconds. Therefore, it is confirmed that the TiN layer can be removed using WCl₅ gas. It is also confirmed that the Ti layer can be removed using WCl₅ gas in the same way as the TiN layer.

According to the present disclosure in some embodiments, it is possible to remove a first metal adhering to a side wall surface of a recess portion by a second metal halide gas that reacts with the first metal.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A substrate processing method, comprising:
by supplying a first metal halide gas including a first metal to a substrate in which an insulator layer is deposited on a silicon layer and a recess portion is formed in the insulator layer, forming a metal layer of the first metal included in the first metal halide gas on a surface of the silicon layer exposed in the recess portion; and
subsequently, by supplying a second metal halide gas, which includes a second metal different from the first metal and reacts with the first metal, to the substrate in which the silicon of the silicon layer is diffused to the metal layer to form a metal silicide layer, removing the first metal adhering to a side wall surface of the recess portion.

2. The substrate processing method of claim 1, further comprising, after the forming the metal layer, oxidizing the first metal adhering to the side wall surface by heating the substrate in an atmosphere in which an oxidizing gas is supplied,
wherein in the removing the first metal, the first metal oxidized in the oxidizing the first metal is removed.

3. The substrate processing method of claim 1, wherein the first metal is titanium, and metal silicide of the metal silicide layer is titanium silicide.

4. The substrate processing method of claim 3, wherein the first metal halide gas is a TiCl₄ gas.

5. The substrate processing method of claim 3, wherein the second metal halide gas is a WCl₅ gas.

6. The substrate processing method of claim 1, further comprising, after the removing the first metal, forming a conductor on the substrate and embedding the conductor in the recess portion.

7. A substrate processing apparatus, comprising:
a first processing module including:
a processing container having a stage on which a substrate is placed; and
a first gas supplier configured to supply a first metal halide gas including a first metal to the processing container;
a second processing module including:
a processing container having a stage on which the substrate is placed; and
a second gas supplier configured to supply a second metal halide gas including a second metal different from the first metal and reacting with the first metal to the processing container; and
a controller,
wherein the controller is configured to output a control signal for executing:
forming a metal layer of the first metal included in the first metal halide gas on a surface of a silicon layer exposed in a recess portion by placing, on the stage of the first processing module, the substrate in which an insulator layer is deposited on the silicon layer and the recess portion is formed in the insulator layer and supplying the first metal halide gas to the processing container of the first processing module from the first gas supplier; and
subsequently, removing the first metal adhering to a side wall surface of the recess portion by placing, on the stage of the second processing module, the substrate in which the silicon of the silicon layer is diffused to the metal layer to form a metal silicide layer and supplying the second metal halide gas to the processing container of the second processing module from the second gas supplier.

8. The substrate processing apparatus of claim 7, wherein the first processing module and the second processing module share the stage and the processing container.

9. The substrate processing apparatus of claim 7, further comprising:
a vacuum transfer chamber to which the processing container of the first processing module and the processing container of the second processing module are connected; and
a substrate transfer mechanism disposed within the vacuum transfer chamber,
wherein the controller is further configured to output a control signal for executing:
after the forming the metal layer of the first metal, transferring the substrate to the stage of the second processing module from the stage of the first processing module via the vacuum transfer chamber by the substrate transfer mechanism; and
subsequently, removing the first metal.

10. The substrate processing apparatus of claim 7, further comprising
a third processing module including:
a processing container having a stage on which the substrate is placed; and
a third gas supplier configured to supply an oxidizing gas to the processing container,
wherein the controller is further configured to output a control signal for executing:
after the forming the metal layer, oxidizing the first metal adhering to the side wall surface by placing the substrate on the stage of the third processing module and heating the substrate in an atmosphere in which the oxidizing gas is supplied from the third gas supplier; and
in the removing the first metal, removing the first metal oxidized in the oxidizing the first metal.

11. The substrate processing apparatus of claim 7, wherein the first metal is titanium, and metal silicide of the metal silicide layer is titanium silicide.

12. The substrate processing apparatus of claim 11, wherein the first metal halide gas is a TiCl₄ gas.

13. The substrate processing apparatus of claim 11, wherein the second metal halide gas is a WCl₅ gas.

14. The substrate processing apparatus of claim 7, further comprising:
a fourth processing module including:
a processing container having a stage on which the substrate is placed; and
a fourth gas supplier configured to supply a raw material gas of a conductor to the processing container,
wherein the controller is further configured to output a control signal for executing:
after the removing the first metal, performing film formation of the conductor on the substrate by placing the substrate on the stage of the fourth processing module and supplying the raw material gas to the processing container from the fourth gas supplier; and
embedding the conductor in the recess portion.
